(19) United States
(12) Patent Application Publication
(10) Pub. No.: US 2020/0308325 A1
(43) Pub. Date: Oct. 1, 2020

(54) COMPOSITION AND METHOD FOR FORMING INSULATING PART

(71) Applicant: TOKYO OHKA KOGYO CO., LTD., Kawasaki-shi (JP)

(72) Inventors: Kazuaki Ebisawa, Kawasaki-shi (JP); Kazuhide Uno, Kawasaki-shi (JP); Yuki Tomioka, Kawasaki-shi (JP)

(21) Appl. No.: 16/824,037

(22) Filed: Mar. 19, 2020

(30) Foreign Application Priority Data
Mar. 28, 2019 (JP) 2019-064574

(51) Int. Cl. C08F 212/08; G03F 7/039; G03F 7/033; G03F 7/20; G03F 7/32; G03F 7/16; G03F 7/38; H01B 3/30

(52) U.S. Cl. CPC C08F 212/08; G03F 7/039; G03F 7/033; H01B 3/30; G03F 7/325; G03F 7/168; G03F 7/38; G03F 7/2004

(57) ABSTRACT

A composition used to form an insulating part for insulating metal wiring in the electric and electronic devices having the metal wiring, and including a resin (A) having a group represented by formula (a1). The group represented by formula (a1) is bonded to a carbon atom in an aliphatic hydrocarbon group or an aromatic group of a main chain and/or a side chain of resin (A), and the carbon atom is located in a position other than a terminal of main chain of resin (A).

This application claims priority TO Japanese Patent Application No. 2019-064574, filed Mar. 28, 2019, the entire content of which is incorporated herein by reference.

### BACKGROUND OF THE INVENTION

### Field of the Invention

The present invention relates to a composition to be used for forming an insulating part for insulating metal wiring in electric and electronic devices having the metal wiring, and a method for forming an insulating part.

### Related Art

In recent years, in communication equipment such as a portable telephone, frequency has been higher. Accordingly, an insulating part for insulating metal wiring of the communication equipment is required to respond to higher frequency. Herein, as a frequency becomes higher, a transmission loss is increased. With the increase in transmission loss, an electric signal is attenuated. Therefore, as response to higher frequency, reduction in transmission loss is required.

In order to reduce transmission loss, technology of forming an insulating layer using a material having a low dielectric constant and a low dielectric loss tangent has been disclosed (see, for example, Patent Document 1).

Patent Document 1: Japanese Unexamined Patent Application, Publication No. 2004-87639.

### SUMMARY OF THE INVENTION

However, the technology of Patent Document 1 is a technology using a resin composition having a specific structure, specifically a resin composition containing a cross-linking component represented by the formula (1) described in Patent Document 1. Therefore, technology using other compositions has been demanded. Note here that response to high frequency is also required in electric and electronic devices other than communication equipment including network-related electronic equipment such as a server, electronic equipment such as a computer, and the like.

Furthermore, in manufacturing electric and electronic devices, in many cases, an insulating part is formed from a composition, and then members such as wiring are formed by heating. Accordingly, the insulating part is also required to have heat resistance. When an insulating part is formed from a composition, the insulating part can easily be formed by a coating method. Accordingly, it is desirable that the composition can be applied to the coating method, that is, the composition is excellent in film formability by the coating method.

The present invention has been made in view of the above-mentioned problems. An object of the present invention is to provide a composition to be used for forming an insulating part for insulating metal wiring in electric and electronic devices having the metal wiring, the composition capable of being formed into the insulating part having a low dielectric constant and a low dielectric loss tangent and having excellent heat resistance, and having excellent film formability, and a method for forming an insulating part.

The present inventors have found that in forming an insulating part for insulating metal wiring in electric and electronic devices having the metal wiring, a composition including a resin (A) having a group represented by the following formula (a1) at a specific position can be formed into an insulating part having a low dielectric constant and a low dielectric loss tangent and excellent heat resistance, and having excellent film formability, and the present inventors have completed the present invention.

A first aspect of the present invention is a composition to be used for forming an insulating part for insulating metal wiring in electric and electronic devices having the metal wiring, wherein the composition includes a resin (A) having a group represented by the following formula (a1), the group represented by the formula (a1) is bonded to a carbon atom in an aliphatic hydrocarbon group or an aromatic group in a main chain and/or a side chain of the resin (A), the carbon atom being located in a position other than a terminal of the main chain of the resin (A), the group represented by the formula (a1) is a group represented by the following formula:

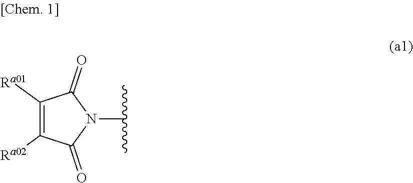

(wherein, in the formula (a1), R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms.)

A second aspect of the present invention is a method for forming an insulating part, the method including: applying or filling the composition according to the first aspect to at least a position provided with an insulating part on a substrate for electric and electronic devices having metal wiring; and exposing the applied or filled composition.

The present invention can provide a composition to be used for forming an insulating part for insulating metal wiring in electric and electronic devices having the metal wiring, the composition capable of being formed into the insulating part having a low dielectric constant and a low dielectric loss tangent and excellent heat resistance, and having excellent film formability, and a method for forming an insulating part.

### BRIEF DESCRIPTION OF THE DRAWINGS

FIG. 1 is a view showing ¹³C NMR measurement results of a protected resin 1.

FIG. 2 is a view showing ¹³C NMR measurement results of a resin P1.

### DETAILED DESCRIPTION OF THE INVENTION

### <<Composition>>

A composition is used for forming an insulating part for insulating metal wiring in electric and electronic devices having the metal wiring. The electric and electronic devices are not particularly limited, and examples thereof include communication equipment such as a portable telephone, network-related electronic equipment such as a server, electronic equipment such as a computer, particularly semiconductor components of these equipment, and specifically a semiconductor package called a wafer-level package. These electric and electronic devices have metal wiring made of metal such as copper and an alloy on a substrate for electric and electronic devices. Examples of the substrate for electric and electronic devices having metal wiring include a silicon substrate, and a silicon substrate provided thereon with various layers or members. This metal wiring and another metal wiring or a conductive member are insulated from each other with an insulating part formed of the composition of the present invention. Use of the composition including the below-mentioned components enables the insulating part having a low dielectric constant and a low dielectric loss tangent (tan δ) to be formed. Therefore, the composition including the below-mentioned components is suitable for an insulating part for insulating metal wiring of electric and electronic devices using high frequency signals. Note here that in the present application, “high frequency” means a frequency of 3 GHz or more. Furthermore, since with the above-mentioned composition, an insulating part having excellent heat resistance can be formed, for example, it can be used for electric and electronic devices in which an insulating part is formed of composition is formed and then other members are formed by heating. Furthermore, the composition of the present invention is excellent in the film formability by a coating method. In other words, when a film is formed by a coating method, the composition is free from occurrence of cracks and crystals, occurrence of tackiness (stickiness) occurs, and has good compatibility of components. Therefore, an insulating part can be formed by the coating method that is an easy method. Hereinafter, the composition of the present invention is described in detail.

### <Resin (A)>

A composition contains a resin (A) having a group represented by the following formula (a1). The group represented by the following formula (a1) is bonded to a carbon atom in an aliphatic hydrocarbon group or an aromatic group in at least one of a main chain and a side chain of the resin (A), the carbon atom being located in a position other than a terminal of the main chain of the resin (A).

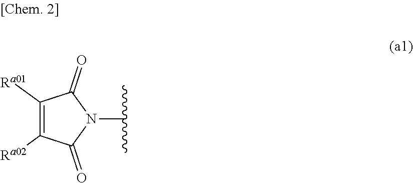

(wherein, in the formula (a1), R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms.)

The alkyl group having 1 or more and 6 or less carbon atoms as R^{a01} and R^{a02} in the formula (a1) may be linear or branched, and specific examples thereof include a methyl group, an ethyl group, an n-propyl group, an n-butyl group, an n-pentyl group, an n-hexyl group, an isopropyl group, an isobutyl group, a sec-butyl group, a tert-butyl group, an isopentyl group, a neopentyl group, a tert-pentyl group, an isohexyl group. Specific examples of the cycloalkyl group having 3 or more and 8 or less carbon atoms as R^{a01} and R^{a02} in the formula (a1) include a cyclopropyl group, a cyclobutyl group, a cyclopentyl group, and a cyclohexyl group. Specific examples of the aryl group having 6 or more and 12 or less carbon atoms as R^{a01} and R^{a02} in the formula (a1) include a phenyl group, a biphenyl group, a 1-naphthyl group, and a 2-naphthyl group. It is preferable that both R^{a01} and R^{a02} in the formula (a1) are a hydrogen atom. When both of the R^{a01} and R^{a02} are a hydrogen atom, since excellent polymerizability is achieved, a composition having excellent curability can be obtained. When both of the R^{a01} and R^{a02} are a hydrogen atom, a group represented by the formula (a1) is a non-substituted maleimide group.

In the resin (A) contained by the composition, the group represented by the above formula (a1) is bonded to a carbon atom in an aliphatic hydrocarbon group or an aromatic group in a main chain and/or a side chain of the resin (A), the carbon atom being located in a position other than a terminal of the main chain of the resin (A). In other words, the resin (A) has a structure in which a hydrogen atom bonded to the carbon atom in the aliphatic hydrocarbon group or the aromatic group of the main chain and/or the side chain of the resin, the carbon atom being located in a position other than the terminal of the main chain of the resin (A), is substituted with the group represented by the formula (a1). As the resin, a polymer of a monomer having an unsaturated double bond. Examples of such a resin include a (meth)acrylic resin and a polystyrene resin. Note here that in this specification, the “(meth)acryl” means both “acryl” and “methacryl.” The “(meth)acrylic resin” is a resin including a constituent unit derived from one or more types of monomers selected from the group consisting of (meth)acrylic acid, (meth)acrylic ester, and optionally N-substituted (meth)acrylamide. The (meth)acrylic resin may include a constituent unit derived from a monomer other than the (meth)acrylic acid, (meth)acrylic acid ester, and optionally N-substituted (meth)acrylamide. The “polystyrene resin” is a resin including a constituent unit derived from styrene and/or styrene derivative. In the specification of the present application, a resin including a constituent unit derived from one or more monomers selected from the group consisting of (meth)acrylic acid, (meth)acrylic ester, and optionally N-substituted (meth)acrylamide, and a constituent unit derived from styrene and/or styrene derivative are handled as a (meth)acrylic resin for convenience sake. Note here that in this specification, the “side chain” means a molecular chain branched from the main chain. For example, when the resin is a (meth)acrylic resin, a carboxy group, an ester group, an optionally N-substituted amide group, and a methyl group, which are bonded to an α-carbon atom of monomer of the (meth)acrylic resin, are a side chain. When the resin is a styrene resin, a phenyl group bonded to a carbon atom derived from a carbon-carbon double bond of monomer of the styrene resin, and derivatives thereof are a side chain.

In the resin (A), since the group represented by the above formula (a1) is bonded to a carbon atom in an aliphatic hydrocarbon group or an aromatic group in a main chain and/or a side chain of the resin (A), the carbon atom being located in a position other than the terminal of the main chain of the resin (A), the group represented by the formula (a1) is at least a part of the side chain of the resin (A1). For example, when the group represented by the above formula (a1) is bonded to a carbon atom in an aliphatic hydrocarbon group or an aromatic group in a main chain of the resin (A), the carbon atom being located in a position other than the terminal of the main chain of the resin (A), the resin (A) has a structure including the aliphatic hydrocarbon group or the aromatic group in the main chain of the resin (A), in which the group represented by the formula (a1) is bonded to a carbon atom in the aliphatic hydrocarbon group or the aromatic group in the main chain. Therefore, the group represented by the formula (a1) is the side chain of the resin (A1). Furthermore, when the group represented by the above formula (a1) is bonded to a carbon atom in an aliphatic hydrocarbon group or an aromatic group in a side chain of the resin (A), the resin (A) has a structure including the aliphatic hydrocarbon group or the aromatic group in the side chain, and the group represented by the formula (a1) is bonded to a carbon atom in the aliphatic hydrocarbon group or the aromatic group of the side chain. Therefore, the group represented by the formula (a1) is a part of the side chain of the resin (A1).

Note here that in the resin (A), it is only required that the group represented by the above formula (a1) is bonded to a carbon atom in an aliphatic hydrocarbon group or an aromatic group in a main chain and/or a side chain of the resin (A), the carbon atom being located in a position other than the terminal of the main chain of the resin (A). In addition, the group represented by the above formula (a1) may be bonded to a carbon atom positioned in the terminal of the main chain of the resin (A). Note here that even when the group represented by the above formula (a1) is bonded to only a carbon atom positioned in the terminal of the main chain of the resin (A), as shown in the below-mentioned Comparative Examples, the formed insulating part has poor heat resistance, and it is difficult to use the insulating part in the electric and electronic devices having metal wiring as an insulating part for insulating the metal wiring. Furthermore, the group represented by the formula (a1) is preferably included in the constituent unit of the resin.

The main chain of the resin (A) is preferably a main chain derived from a (meth)acrylic resin, or a main chain derived from a polystyrene resin. Since a (meth)acrylic resin or a polystyrene resin has a low dielectric constant and a dielectric loss tangent, when the main chain is a main chain derived from a (meth)acrylic resin, or a main chain derived from polystyrene resin, the dielectric constant or the dielectric loss tangent in the formed insulating part can be further reduced.

A molecular weight of the resin (A) is not particularly limited as long as the effect of the present invention is not impaired, but the mass average molecular weight (Mw) is preferably 4000 or more, more preferably 5000 or more, and further preferably 10000 or more. The molecular weight of the resin (A) is preferably 100000 or less, and more preferably 80000 or less as the mass average molecular weight (Mw). In this specification, the mass average molecular weight (Mw) is a measurement value based on polystyrene by gel permeation chromatography (GPC).

In this way, the resin (A) having the group represented by the formula (a1) at a specific position has the group represented by the formula (a1) such as a maleimide group which is bonded to a carbon atom in the aliphatic hydrocarbon group or the aromatic group and positioned in the side chain of the resin, and the group represented by the formula (a1) is a radical polymerizable group. Therefore, an insulating part having a low dielectric constant and a low dielectric loss tangent and excellent heat resistance can be formed by polymerization by expose or heating. For example, the dielectric constant of the formed insulating part can be less than 3.00. Furthermore, the dielectric loss tangent of the formed insulating part can be less than 0.01. Furthermore, the glass-transition temperature (Tg) of the formed insulating part can be 150° C. or more. Furthermore, a composition including the resin (A) is excellent in film formability in the coating method. In other words, a film is formed by the coating method, a film is free from occurrence of crack and crystal and tackiness (stickiness), and has good compatibility of components. Therefore, an insulating part can be formed by the coating method being an easy method.

Moreover, the resin (A) is excellent in the solvent solubility. Therefore, the composition including the resin (A) can be applied as a negative composition in a developing process with the solvent. In particular, the resin (A) may be soluble in an alkaline aqueous solution in some cases although depending on the structure. Such cases include, for example, a case where the resin (A) has an alkali soluble group such as a carboxy group and a phenolic hydroxyl group. A composition including such an alkali-soluble resin (A) can be applied as a negative composition to an alkaline developing process. Furthermore, with the composition including the resin (A), an insulating part having a desired pattern shape can be formed by selective exposure in which exposure is performed in a position selective manner.

The content of the resin (A) in the composition is not particularly limited, but the content of the resin (A) is preferably 5% by mass or more and 100% by mass or less with respect to the total solid content of the composition.

A method for producing the resin (A) is not particularly limited. Specifically, the resin (A) can be produced by a producing method including a first step of condensing a primary amino group in a resin (a raw material compound) having a primary amino group, and a dicarboxylic anhydride represented by the following formula (a2):

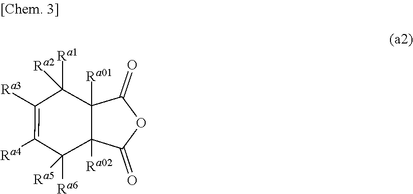

(wherein, in the formula (a2), R^{a01} and R^{a02} are the same as R^{a01} and R^{a02} in the formula (a1), R^{a1} to R^{a6} are each independently a hydrogen atom, a halogen atom, an alkyl group having 1 or more and 4 or less carbon atoms, or an alkoxy group having 1 or more and 4 or less carbon atoms, R^{a1} and R^{a5} may be bonded to each other to form —O—, —S—, —CH₂—, or —CR^{a7}R^{a8}—, and R^{a3} and R^{a4} may be bonded to each other to form a ring having 6 or more and 12 or less carbon atoms, R^{a7} to R^{a8} are each independently a hydrogen atom, an alkyl group having 1 or more and 4 or less carbon atoms or an alkoxy group having 1 or more and 4 or less carbon atoms) to generate a group represented by the following formula (a3):

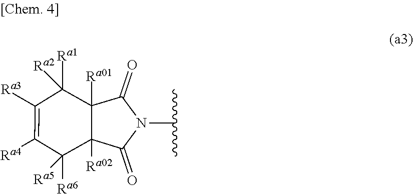

(wherein in the formula (a3), R^{a01} and R^{a02} are the same as R^{a01} and R^{a02} in the formula (a1), and R^{a1} to R^{a6} are the same as R^{a1} to R^{a6} in the formula (a2)); and a second step of heating the compound generated in the first step and having a group represented by the formula (a3), and converting the group represented by the formula (a3) into the group represented by the formula (a1).

Specific examples of a halogen atom as R^{a1} to R^{a6} in the formula (a2) include a chlorine atom, a fluorine atom, a bromine atom, and an iodine atom. The alkyl group having 1 or more and 4 or less carbon atoms as R^{a1} to R^{a6} in the formula (a2) may be a linear or branched chain, and specific examples thereof include a methyl group, an ethyl group, an n-propyl group, an n-butyl group, an isopropyl group, an isobutyl group, an sec-butyl group, and a tert-butyl group. The alkoxy group having 1 or more and 4 or less carbon atoms as R^{a1} to R^{a6} in the formula (a2) may be a linear or branched chain, and specific examples thereof include a methoxy group, an ethoxy group, an n-propoxy group, an isopropoxy group, and an n-butoxy group. The alkyl group having 1 or more and 4 or less carbon atoms as R^{a7} and R^{a8} and an alkoxy group having 1 or more and 4 or less carbon atoms are the same as the alkyl group having 1 or more and 4 or less carbon atoms and the alkoxy group having 1 or more and 4 or less carbon atoms as R^{a1} to R^{a6}.

In the first step, a primary amino group in the resin (raw material compound) having the primary amino group, and a dicarboxylic anhydride represented by the above formula (a2) are condensed to each other to generate a group represented by the above formula (a3). Thus, a resin having the group represented by the formula (a3) is obtained.

As the resin (raw material compound) having a primary amino group, a polymer of a monomer having an unsaturated double bond is exemplified. Examples of such resins include a (meth)acrylic resin having a primary amino group, and a polystyrene resin having a primary amino group. More specific examples thereof include a (meth)acrylic resin having a primary amino group at a terminal of a side chain, and a polystyrene resin having a primary amino group at the terminal of the side chain. The “(meth)acrylic resin having a primary amino group” is a (meth)acrylic resin including a constituent unit having a primary amino group. The constituent unit having a primary amino group may be a constituent unit derived from (meth)acrylic ester, or a constituent unit derived from an N-substituted body of (meth)acrylamide, or constituent units other than these constituent units. The constituent unit having a primary amino group is preferably a constituent unit derived from (meth)acrylic ester, and/or a constituent unit derived from the N-substituted body of (meth)acrylamide. The “polystyrene resin having a primary amino group” is a polystyrene resin including a constituent unit having a primary amino group. The constituent unit having a primary amino group may be a constituent unit derived from amino styrene such as p-amino styrene, m-amino styrene, and o-amino styrene, or a constituent unit derived from styrene derivatives having an amino group such as p-aminomethylstyrene, m-aminomethylstyrene, and o-aminomethylstyrene, or constituent units other than these constituent units. The constituent unit having a primary amino group is preferably a constituent unit derived from amino styrene, and/or a constituent unit derived from styrene derivative having an amino group. Resins including the primary amino group, such as a (meth)acrylic resin having a primary amino group and a polystyrene resin having a primary amino group preferably include a primary amino group at the terminal of the side chain. In the (meth)acrylic resin having a primary amino group at the terminal of the side chain, and the polystyrene resin having a primary amino group at the terminal of the side chain, the terminal of the side chain to which a primary amino group when the side chain is a branched chain is bonded may be any terminals of two or more of the branched chains. Furthermore, when the structure of the terminals of the side chain has a ring structure, an arbitrary position of the ring constituting the ring structure is a terminal of the side chain to which the primary amino group is bonded. For example, when the side chain includes an α-naphthyl group or β-naphthyl group, the arbitrary position on the naphthalene ring is a terminal of the side chain. Furthermore, when the group constituting the side chain is a 1-phenyl ethyl group being a branched chain, the terminal of the side chain is a methyl group corresponding to the terminals of the two branched chains and arbitrary position on the phenyl group.

In method for producing the resin (A), the resin (raw material compound) having a primary amino group is produced preferably by a method including producing a raw material compound being a resin by homopolymerizing a monomer having a primary amino group; or producing a raw material compound being a resin by copolymerizing a monomer having a primary amino group and a comonomer. Examples of the monomer having a primary amino group include (meth)acrylates such as aminomethyl (meth)acrylate, 2-aminoethyl (meth)acrylate, 3-aminopropyl (meth)acrylate, 4-aminophenyl (meth)acrylate, 3-aminophenyl (meth)acrylate, 2-aminophenyl (meth)acrylate, 4-aminophenylmethyl (meth)acrylate, 3-aminophenylmethyl (meth)acrylate, and 2-aminophenylmethyl (meth)acrylate; (meth)acrylamides such as N-2-aminoethyl (meth)acrylamide, N-3-aminopropyl (meth)acrylamide, N-4-aminophenyl (meth)acrylamide, N-3-aminophenyl (meth)acrylamide, and N-2-aminophenyl (meth)acrylamide; amino styrene such as p-amino styrene, m-amino styrene, and o-amino styrene; aminoalkylstyrene such as p-aminomethylstyrene, m-aminomethylstyrene, and o-aminomethylstyrene, and the like.

The comonomer is a monomer other than the monomer having a primary amino group. Examples of the comonomer include a compound represented by the following formula (a-I).

CH₂═CR^{a11}—CO—O—R^{a10} (a-I)

In the formula (a-I), R^{a10} is a monovalent organic group, and R^{a11} is a hydrogen atom or a methyl group. This organic group may include a bond or a substituent other than a hydrocarbon group such as a hetero atom in the organic group, and the like. Furthermore, this organic group may be linear or branched or cyclic.

The substituent other than the hydrocarbon group in the organic group of R^{a10} is not particularly limited as long as the present invention are not impaired, and examples thereof include a halogen atom, a hydroxyl group, a mercapto group, a sulfide group, a cyano group, an isocyano group, a cyanato group, an isocyanato group, a thiocyanato group, an isothiocyanato group, a silyl group, a silanol group, an alkoxy group, an alkoxycarbonyl group, a carbamoyl group, a thiocarbamoyl group, a nitro group, a nitroso group, a carboxy group, a carboxylate group, an acyl group, an acyloxy group, a sulfino group, a sulfo group, a sulfonato group, a phosphino group, a phosphinyl group, a phosphono group, a phosphonato group, a hydroxy imino group, an alkyl ether group, an alkylthioether group, an arylether group, an arylthioether group, an N-monosubstituted amino group, an N,N-disubstituted amino group, and the like. The hydrogen atom included in the above-mentioned substituents may be substituted with a hydrocarbon group. Furthermore, a hydrocarbon group included in the above-mentioned substituent may be any of linear, branched, and cyclic.

As R^{a10}, an alkyl group, an aryl group, an aralkyl group, or a heterocyclic group is preferable. These groups may be substituted with a halogen atom, a hydroxyl group, an alkyl group, or a heterocyclic group. Furthermore, when these groups include an alkylene moiety, the alkylene moiety may be interrupted by an ether bond, a thioether bond, or an ester bond.

When the alkyl group is linear or branched, the number of carbon atoms is preferably 1 or more and 20 or less, more preferably 1 or more and 15 or less, and particularly preferably 1 or more and 10 or less. Suitable examples of the alkyl group include a methyl group, an ethyl group, an n-propyl group, an isopropyl group, an n-butyl group, an isobutyl group, an sec-butyl group, a tert-butyl group, an n-pentyl group, an isopentyl group, an sec-pentyl group, a tert-pentyl group, an n-hexyl group, an n-heptyl group, an n-octyl group, an isooctyl group, an sec-octyl group, a tert-octyl group, an n-nonyl group, an isononyl group, an n-decyl group, an isodecyl group, and the like.

When the alkyl group is an alicyclic group, or a group including an alicyclic group, examples of the suitable alicyclic group included in the alkyl group include monocyclic alicyclic groups such as a cyclopentyl group and a cyclohexyl group, polycyclic alicyclic groups such as an adamanthyl group, a norbornyl group, an isobornyl group, a tricyclononyl group, a tricyclodecyl group, and a tetracyclo dodecyl group.

The other preferable examples of the comonomer include (meth)acrylamide, unsaturated carboxylic acid, an allyl compound, vinyl ether, vinyl ester, styrene, and the like. These comonomers can be used singly or in combination of two or more.

Examples of (meth)acrylamides include (meth)acrylamide; N-alkyl(meth)acrylamide such as N-methyl(meth)acrylamide, N-ethyl(meth)acrylamide, N-n-propyl(meth)acrylamide, N-isopropyl(meth)acrylamide, and N-n-butyl(meth)acrylamide; N-aryl(meth)acrylamide such as N-phenyl(meth)acrylamide, N-α-naphthyl(meth)acrylamide, and N-β-naphthyl(meth)acrylamide; N,N-dialkyl(meth)acrylamide such as N,N-dimethyl(meth)acrylamide, N,N-diethyl(meth)acrylamide, N,N-di-n-propyl(meth)acrylamide, and N,N-di-n-butyl(meth)acrylamide; N,N-diaryl(meth)acrylamide such as N,N-diphenyl(meth)acrylamide; and other N,N disubstituted (meth)acrylamide such as N-methyl-N-phenyl(meth)acrylamide, and N-hydroxyethyl-N-methyl(meth)acrylamide.

Examples of unsaturated carboxylic acid include monocarboxylic acid such as crotonic acid; dicarboxylic acid such as maleic acid, fumaric acid, citraconic acid, mesaconic acid, and itaconic acid; anhydride of these dicarboxylic acid, and the like.

Examples of the allyl compound include allyl esters such as allyl acetate, allyl caproate, allyl caprylate, allyl laurate, allyl palmitate, allyl stearate, allyl benzoate, allyl acetoacetate and allyl lactate; and allyloxyethanol, and the like.

Examples of the vinyl ethers include an alkyl vinyl ether such as hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether or tetrahydrofurfuryl vinyl ether; and a vinyl aryl ether such as vinyl phenyl ether, vinyl tolyl ether, vinyl chlorophenyl ether, vinyl-2,4-dichlorophenyl ether, vinyl naphthyl ether or vinyl anthranyl ether.

Examples of the vinyl esters include vinyl butyrate, vinyl isobutyrate, vinyl trimethyl acetate, vinyl diethyl acetate, vinyl valate, vinyl caproate, vinyl chloroacetate, vinyl dichloroacetate, vinyl methoxyacetate, vinyl butoxyacetate, vinyl phenyl acetate, vinyl acetoacetate, vinyl lactate, vinyl-β-phenyl butyrate, vinyl benzoate, vinyl salicylate, vinyl chlorobenzoate, vinyl tetrachlorobenzoate and vinyl naphthoate.

Examples of the styrenes include styrene; alkyl styrene such as methylstyrene, dimethylstyrene, trimethylstyrene, ethylstyrene, diethylstyrene, ispropylstyrene, butylstyrene, hexylstyrene, cyclohexylstyrene, decylstyrene, benzylstyrene, chloromethylstyrene, trifluoromethylstyrene, ethoxymethylstyrene or acetoxymethylstyrene; alkoxystyrene such as methoxystyrene, 4-methoxy-3-methylstyrene or dimethoxystyrene; and halostyrene such as chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene or 4-fluoro-3-trifluoromethylstyrene.

When the monomer having a primary amino group and the comonomer are copolymerized, the ratio of the monomer having a primary amino group to the comonomer is not particularly limited, but the ratio of the monomer having a primary amino group:comonomer is, for example, 5 to 50:50 to 95 on a molar basis.

The compound represented by the formula (a2) includes a compound represented by the following formula (a2-1):

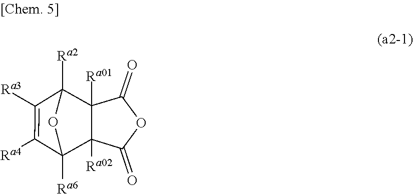

(wherein, in the formula (a2-1), R^{a01}, R^{a02}, R^{a2}, R^{a3}, R^{a4}, and R^{a6} are the same as R^{a01}, R^{a02}, R^{a2}, R^{a3}, R^{a4}, and R^{a6} in the formula (a2)).

The compound represented by the formula (a2) can be obtained by, for example, a Diels-Alder reaction between the compound represented by the following formula and a conjugate diene compound corresponding to the structure of the compound represented by the formula (a2). Conditions for the Diels-Alder reaction may be appropriately set according to types of raw materials to be used, and reaction in an organic solvent may be performed.

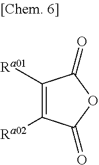

Examples of the organic solvent to be used in the Diels-Alder reaction include esters such as ethyl acetate, butyl acetate, and cellosolve acetate; ketones such as acetone, methyl ethyl ketone, isobutyl ketone, and methyl isobutyl ketone; esters such as ethyl acetate, butyl acetate, and diethyl malonate; amides such as N-methyl-pyrrolidone, and N,N-dimethylformamide; ethers such as diethyl ether, ethyl cyclopentyl ether, tetrahydrofuran, and dioxane; aromatic hydrocarbons such as toluene, and xylene; aliphatic hydrocarbons such as hexane, heptane, octane, and decahydronaphthalene, and halogenated hydrocarbons such as methylene chloride, and ethylene chloride; dimethyl sulfoxide, dimethyl sulfonamide, and the like. As the organic solvent to be used, one kind of solvent may be used, or an arbitrary combination of two more kinds of solvents may be used. The reaction temperature that can be employed is, for example, in a range of −10° C. to 200° C., preferably in a range of 0° C. to 150° C., and more in a range of 5° C. to 120° C. The reaction time that can be employed is, for example, 5 minutes or more and 12 hours or less, 10 minutes or more and 10 hours, and 30 minutes or more and 8 hours or less.

The condensation in the first step is usually performed using a condensing agent. Examples of the dehydration-condensation agent include carbonyl diimidazole, a carbodiimide compound, and the like. The addition of the condensing agent may be performed to a reactor vessel in which the Diels-Alder reaction was performed, or may be performed by separately isolating the product in the Diels-Alder reaction and dissolving it in an organic solvent or the like, again. As the organic solvents to be used in the condensation, the same organic solvents to be used for the Diels-Alder reaction can be employed. The reaction temperature that can be employed is, for example, in a range of −10° C. to 200° C., preferably in a range of 0° C. to 150° C., and more in a range of 5° C. to 120° C. The reaction time that can be employed is, for example, 5 minutes or more and 12 hours or less, 10 minutes or more and 10 hours or less, and 30 minutes or more and 8 hours or less.

Note here that a compound having a group represented by the above formula (a3) obtained by carrying out the first step may be isolated after the first step. When the compound having the group represented by the above formula (a3) is a resin, the isolation is performed, for example, by pouring a reaction solution after condensation in the first step into a poor solvent to solidify thereof, and collecting by filtering thereof.

In the second step, the compound having the group represented by the above formula (a3), generated in the first step, is heated to convert the group represented by the above formula (a3) into the group represented by the above formula (a1) (reverse Diels-Alder reaction). Thus, a resin (A) including the group represented by the above formula (a1) is obtained. The group represented by the above formula (a1) can be introduced into all or a part of the amino group derived from the monomer having a primary amino group as the raw material compound depending on the use amount of the compound represented by the formula (a2).

The reverse Diels-Alder reaction in the second step is performed in, for example, an organic solvent. As the organic solvent to be used, the same organic solvent as that used in the Diels-Alder reaction can be employed, but for performing a reaction by heating, the solvent has a boiling point of preferably 60° C. or more, more preferably 80° C. or more, and further preferably 100° C. or more. The upper limit of the boiling point is not particularly limited, but it is, for example, 350° C. or less. As to the heating in the second step, the reaction temperature that can be employed is, for example, in a range of 60° C. to 280° C., preferably in a range of 80° C. to 250° C., and more preferably in a range of 100° C. to 225° C. The reaction time that can be employed is, for example, 5 minutes or more and 12 hours or less, preferably 10 minutes or more and 10 hours or less, and more preferably 30 minutes or more and 8 hours or less.

Furthermore, a compound having a group represented by the above formula (a1) obtained by carrying out the second step may be isolated after the second step. When the compound having the group represented by the above formula (a1) is a resin, the isolation is performed, for example, by pouring a reaction solution after condensation in the second step into a poor solvent (for example, alcohol solvent) to solidify thereof, and collecting by filtering thereof.

As one example of the method for producing of the resin (A), a reaction formula in a case where a product obtained by copolymerizing amino styrene as the monomer having a primary amino group and styrene as a comonomer is used as a resin (raw material compound) having a primary amino group. In the following reaction formula, the second step shows an example in which reflux is performed in toluene. Furthermore, m and n in the following reaction formula each represent the number of repetition of constituent units.

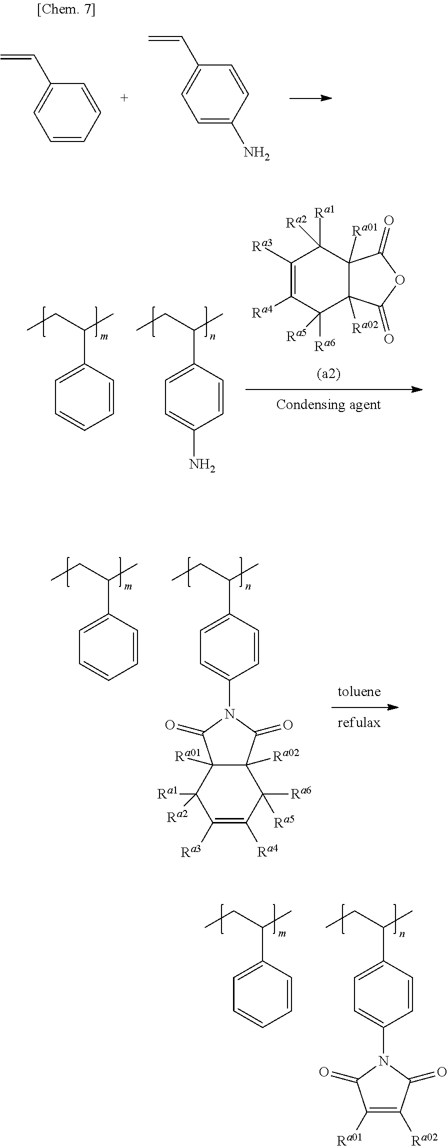

According to such a method for producing the resin (A), a side reaction other than maleimidization is suppressed. As a result of suppression of the side reaction, a resin (A) having a group represented by the formula (a1) can be obtained in a solid state. Herein, “a resin in a solid state” or “a resin in a form of a solid” is also referred to as “a solid resin”. Therefore, for example, in the above-mentioned composition, the resin (A) having a group represented by the formula (a1) as a solid resin can be blended. For example, since a polymer of a monomer having an unsaturated double bond including the group represented by the above formula (a1) at the terminal of the side chain had a problem of gelation, conventionally it was not able to be obtained as the solid resin. Specifically, for example, in a method of reacting a styrene resin having an amino group with maleic anhydride to close a ring, gelation occurred and a solid resin was not obtained. This seems to be because a side reaction other than maleimidization easily occurs. According to the above-mentioned production method, however, a polymer of a monomer, having a group represented by the formula (a1) and an unsaturated double bond, is obtained as a solid resin. Note here that in the specification of the present application, a substituted or non-substituted cyclic imide group represented by the formula (a1) is referred to as a “maleimide group” for convenience sake.

Furthermore, according to the above-mentioned production method, instead of polymerizing a monomer in which a maleimide group has been introduced, a polymer that has been polymerized in advance is used as a raw material compound and a primary amino group of a polymer is reacted to introduce a group represented by the formula (a1). Therefore, the polymerization is not limited to time-consuming cationic polymerization. Therefore, the above-mentioned production method is a simple method.

Furthermore, after the primary amino group and the dicarboxylic anhydride represented by the formula (a2) are condensed to each other to generate a group represented by the formula (a3), the obtained product is heated to convert the group represented by the formula (a3) into a group represented by the formula (a1). Therefore, problems by ring closure reaction do not occur. Thus, a group represented by the formula (a1) can be introduced reliably.

### <Radical Polymerizable Compound (B)>

The above-mentioned composition may further contain a radical polymerizable compound (B). Of course, the above-mentioned composition may not contain a radical polymerizable compound (B). The radical polymerizable compound (B) is a radical polymerizable compound other than the resin (A). The radical polymerizable compound (B) may be compounds having an unsaturated double bond, such as styrene, a styrene polymer, acrylonitrile, (meth)acrylic acid, and (meth)acrylic ester, but it is preferably a radical polymerizable compound having the group represented by the above formula (a1). As the radical polymerizable compound having the group represented by the above formula (a1), a polyfunctional maleimide compound having two or more groups represented by the formula (a1) is preferable, and a bismaleimide compound in which two amino groups of aromatic diamine or aliphatic diamine are substituted with a group represented by the formula (a1) is preferable. Specific examples of aromatic diamine include: p-phenylenediamine; m-phenylenediamine; 2,4-diamino toluene; 4,4′-diamino biphenyl; 4,4′-diamino-2,2′-bis(trifluoromethyl) biphenyl; 3,3′-diaminodiphenyl sulfone; 4,4′-diaminodiphenyl sulfone; 4,4′-diaminodiphenyl sulfide; 4,4′-diaminodiphenylmethane; 4,4′-diamino diphenyl ether; 3,4′-diamino diphenyl ether; 3,3′-diamino diphenyl ether; 1,4-bis(4-aminophenoxy)benzene; 1,3-bis(4-aminophenoxy)benzene; 1,3-bis(3-aminophenoxy) benzene; 4,4′-bis(4-aminophenoxy) biphenyl; bis[4-(4-aminophenoxy)phenyl]sulfone; bis[4-(3-aminophenoxy)phenyl]sulfone; 2,2-bis[4-(4-aminophenoxy)phenyl]propane; 2,2-bis[4-(4-amino phenoxy) phenyl]hexafluoropropane; and the like. Specific examples of aliphatic diamine include pentamethylene diamine, hexamethylene diamine, heptamethylene diamine, 2,3,3-tirmethylpentane-1,5-diamine, and the like. Examples of the radical polymerizable compound having the group represented by the above formula (a1) include 2,2-bis[4-(4-maleimidephenoxy)phenyl]propane and the following compounds (all of which are manufactured by Tokyo Chemical Industry Co., Ltd. (TCI)), and BMI-689, BMI-1400, BMI-1500, BMI-1700, BMI-2700, and BMI-3000 (all of which are manufactured by Designer molecules).

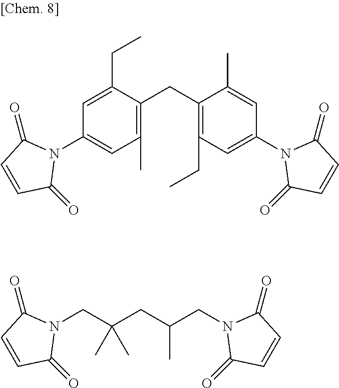 [SMILES: CCc1cc(N2C(=O)C=CC2=O)cc(C)c1Cc1c(C)cc(N2C(=O)C=CC2=O)cc1CC ; CC(CN1C(=O)C=CC1=O)CC(C)(C)CN1C(=O)C=CC1=O]

As the radical polymerizable compound other than the above-mentioned maleimide compound, various radical polymerizable compounds that have been conventionally blended in the radical polymerizable composition can be used without limitation. Specific examples of the radical polymerizable compound other than the maleimide compound include the following compounds.

Examples of the monofunctional radical polymerizable compound include (meth)acryl amide, methylol(meth)acrylamide, methoxymethyl(meth)acrylamide, ethoxymethyl(meth)acrylamide, propoxymethyl(meth)acrylamide, butoxymethoxymethyl(meth)acrylamide, N-methylol(meth)acrylamide, N-hydroxymethyl(meth)acrylamide, (meth)acrylic acid, fumaric acid, maleic acid, maleic anhydride, itaconic acid, itaconic anhydride, citraconic acid, citraconic anhydride, crotonic acid, 2-acrylamide-2-methylpropanesulfonic acid, tert-butylacrylamidesulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerin mono(meth)acrylate, tetrahydrofurfuryl (meth)acrylate, dimethylamino (meth)acrylate, glycidyl (meth)acrylate, 2,2,2-trifluoroethyl (meth)acrylate, 2,2,3,3-tetrafluoropropyl (meth)acrylate, half (meth)acrylate of a phthalic acid derivative, and the like. These monofunctional compounds may be used alone or in combination of two or more kinds thereof.

Examples of the polyfunctional radical polymerizable compound include 1,3-butanediol di(meth)acrylate, 1,4-butanedioldi (meth)acrylate, 1,6-hexanediol di(meth)acrylate, 1,9-nonandiol di(meth)acrylate, 1,10-decanediol di(meth)acrylate, 1,12-dodecanediol di(meth)acrylate, ethoxylated hexanediol di(meth)acrylate, tricyclodecane dimethanol di(meth)acrylate, 2-hydroxy-3-(meta)acryloyloxypropyl (meta)acrylate, dipentaerythritol di(meth)acrylate, diethylene glycol di(meth)acrylate, triethylene glycol di(meth)acrylate, dipropylene glycol di(meth)acrylate, tripropylene glycol di(meth)acrylate, ethoxylated neopentyl glycol di(meth)acrylate, polyethylene glycol di(meth)acrylate, poly(ethylene-propylene)glycol di(meth)acrylate, polytetramethylene glycol di(meth)acrylate, ethoxylated bisphenol A di(meth)acrylate, propoxylated bisphenol A di(meth)acrylate, propoxylated ethoxylated bisphenol A di(meth)acrylate, ethylene glycol di(meth)acrylate, diethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, trimethylolpropane tri(meth)acrylate, glycerin di(meth)acrylate, pentaerythritol triacrylate, pentaerythritol tetraacrylate, dipentaerythritol pentaacrylate, dipentaerythritol hexaacrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl (meth)acrylate, ethylene glycol diglycidyl ether di(meth)acrylate, diethylene glycol diglycidyl ether di(meth)acrylate, phthalic acid diglycidyl ester di(meth)acrylate, glycerin triacrylate, glycerin polyglycidyl ether poly(meth)acrylate, urethane (meth)acrylate (i.e. tolylene diisocyanate), a reaction product of trimethylhexamethylene diisocyanate, hexamethylene diisocyanate, and the like, and 2-hydroxyethyl (meth)acrylate, and methylene bis(meth)acrylamide, (meth)acrylamide methylene ether, a condensation product of polyhydric alcohol and N-methylol(meth)acrylamide, triacryl formal, 2,4,6-trioxohexahydro-1,3,5-triazine-1,3,5-trisethanol triacrylate, 2,4,6-trioxohexahydro-1,3,5-triazine-1,3,5-trisethanol diacrylate, and the like. These polyfunctional compounds may be used alone or in combination of two or more kinds thereof.

The content of the radical polymerizable compound (B) in the composition is not particularly limited, but the content is preferably 10% by mass or more and 70% by mass or less with respect to the total amount of the resin (A) and the radical polymerizable compound (B).

### <Radical Initiator (C)>

The above-mentioned composition preferably includes a radical initiator (C). The radical initiator (C) may be a photo-radical initiator (C1) or a thermal radical initiator (C2), or the photo-radical initiator (C1) and the thermal radical initiator (C2) may be used in combination.

Examples of the photo-radical initiator (C1) include alkylphenone initiators such as Omnirad 651, Omnirad 184, Omnirad 1173, Omnirad 2959, Omnirad 127, Omnirad 907, Omnirad 369, Omnirad 369E, and Omnirad 379EG (all of which are manufactured by IGM Resins B.V.), acylphosphine oxide initiators such as Omnirad TPO H, and Omnirad 819 (all of which are manufactured by IGM Resins B.V.), and oxime ester photopolymerization agents such as Irgacure OXE01, Irgacure OXE02 (all of which are manufactured by BASF).

Specific examples of the photo-radical initiator (C1) include 1-hydroxy-cyclohexylphenylketone, 2-hydroxy-2-methyl-1-phenylpropan-1-one, 1-[4-(2-hydroxyethoxy)phenyl]-2-hydroxy-2-methyl-1-propan-1-one, 1-(4-isopropylphenyl)-2-hydroxy-2-methylpropan-1-one, 1-(4-dodecylphenyl)-2-hydroxy-2-methylpropan-1-one, 2,2-dimethoxy-1,2-diphenylethan-1-one, bis(4-dimethylaminophenyl)ketone, 2-methyl-1-[4-(methylthio)phenyl]-2-morpholinopropan-1-one, 2-benzyl-2-dimethylamino-1-(4-morpholinophenyl)-butan-1-one, 1,2-octanedione,1-[4-(phenylthio)phenyl]-,2-(O-benzoyl oxime ester) (Irgacure OXE01), ethanone-1-[9-ethyl-6-(2-methylbenzoyl)-9H-carbozol-3-yl]-1-(O-acetyloxime) (Irgacure OXE02), 2,4,6-trimethylbenzoyldiphenylphosphineoxide (Omnirad TPO H), bis(2,4,6-trimethyl benzoyl)phenyl phosphine oxide (Omnirad 819), 4-benzoyl-4′-methyldimethylsulfide, 4-dimethylaminobenzoic acid, methyl 4-dimethylaminobenzoate, ethyl 4-dimethylaminobenzoate, butyl 4-dimethylaminobenzoate, 4-dimethylamino-2-ethylhexylbenzoic acid, 4-dimethylamino-2-isoamylbenzoic acid, benzyl-β-methoxyethylacetal, benzyldimethylketal, 1-phenyl-1,2-propanedione-2-(O-ethoxycarbonyl)oxime, methyl O-benzoylbenzoate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, 2-ethylanthraquinone, octamethylanthraquinone, 1,2-benzanthraquinone, 2,3-diphenylanthraquinone, azobisisobutyronitrile, benzoyl peroxide, cumene hydroperoxide, 2-mercaptobenzimidazole, 2-mercaptobenzoxazole, 2-mercaptobenzothiazole, 2-(O-chlorophenyl)4,5-di(m-methoxyphenyl)imidazolyl dimers, benzophenone, 2-chlorobenzophenone, p,p′-bisdiethylaminobenzophenone, 4,4′-bisdiethylaminobenzophenone, 4,4′-dichlorobenzophenone, 3,3-dimethyl-4-methoxybenzophenone, benzyl, benzoin, benzoin methyl ether, benzoin ethyl ether, benzoin isopropyl ether, benzoin-n-butyl ether, benzoin isobutyl ether, benzoin butyl ether, acetophenone, 2,2-diethoxyacetophenone, p-dimethylacetophenone, p-dimethylaminopropiophenone, dichloroacetophenone, trichloroacetophenone, p-tert-butylacetophenone, p-dimethylaminoacetophenone, p-tert-butyltrichloroacetophenone, p-tert-butyldichloroacetophenone, α,α-dichloro-4-phenoxyacetophenone, thioxanthone, 2-methylthioxanthone, 2-isopropylthioxanthone, dibenzosuberone, pentyl-4-dimethylamino benzoate, 9-phenylacridine, 1,7-bis-(9-acridinyl)heptane, 1,5-bis-(9-acridinyl)pentane, 1,3-bis-(9-acridinyl)propane, p-methoxytriazine, 2,4,6-tris(trichloromethyl)-s-triazine, 2-methyl-4,6-bis(trichloromethyl)-s-triazine, 2-[2-(5-methylfuran-2-yl)ethenyl]-4,6-bis(trichloromethyl)-s-triazine, 2-[2-(furan-2-yl)ethenyl-4,6-bis(trichloromethyl)-s-triazine, 2-[2-(4-diethylamino-2-methylphenyl)ethenyl]-4,6-bis(trichloromethyl)-s-triazine, 2-[2-(3,4-dimethoxyphenyl)ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy)styrylphenyl-s-triazine, 2,4-bis-trichloromethyl-6-(2-bromo-4-methoxy)styrylphenyl-s-triazine, and the like. These photopolymerization initiators can be used singly or in combination of two or more of them. Among them, it is particularly preferable to use an oxime ester initiator from the viewpoint of the sensitivity.

Examples of the thermal radical polymerization initiator (C2) include organic peroxide such as ketone peroxide (methyl ethyl ketone peroxide, cyclohexanone peroxide, and the like), peroxy ketal(2,2-bis(tert-butylperoxy)butane, and 1,1-bis(tert-butylperoxy)cyclohexane, and the like), hydroperoxide(tert-butylhydroperoxide, cumene hydroperoxide, and the like), dialkyl peroxide (di-tert-butylperoxide (perbutyl (registered trademark) D (manufactured by NOF CORPORATION), and di-tert-hexyl peroxide(perhexyl (registered trademark) D (manufactured by NOF CORPORATION)), and the like), diacyl peroxide (isobutyryl peroxide, lauroyl peroxide, benzoyl peroxide, and the like), peroxydicarbonate (diisopropyl peroxydicarbonate and the like), peroxyester (tert-butylperoxy isobutylate, 2,5-dimethyl-2,5-di(benzoyl peroxy)hexane, and the like)}; and azo compounds such as 1,1′-azobis(cyclohexane-1-carbonitrile), 2,2′-azobis isobutyronitrile, 2,2′-azobis(2,4-dimethyl-4-methoxyvaleronitrile), 2,2′-azobis(2-methylpropionamidine)dihydrochloride, 2,2′-azobis[2-methyl-N-(2-propenyl)propionamide]dihydrochloride, 2,2′-azobis(2-methylpropionamidine), 2,2′-azobis[2-methyl-N-(2-hydroxyethyl)propionamide], 2,2′-azobis(2-methyl propane), 2,2′-azobis(2,4,4-trimethyl pentane), dimethyl 2,2′-azobis(2-methyl propionate), and the like}.

The content of the radical initiator (C) in the composition is not particularly limited, but it is preferably 0.1 parts by mass or more and 10 parts by mass or less with respect to the total 100 parts by mass of the resin (A) and the radical polymerizable compound (B).

### <Organic Solvent (S)>

The above-mentioned composition usually includes an organic solvent (S). Types of the organic solvent (S) is not particularly limited within a range where the objects of the present invention are not impaired, and can be appropriately selected from organic solvents used for a photosensitive composition.

Specific examples of the organic solvent (S) include ketones such as acetone, methyl ethyl ketone, cyclohexanone, methyl isoamyl ketone, and 2-heptanone; polyhydric alcohols such as ethylene glycol, ethylene glycol monoacetate, diethylene glycol, diethylene glycol monoacetate, propylene glycol, propylene glycol monoacetate, propylene glycol monomethyl ether acetate, dipropylene glycol, monomethyl ether of dipropylene glycol monoacetate, monoethyl ether, monopropyl ether, monobutyl ether, mono phenyl ether, and the derivatives thereof; cyclic ethers such as dioxane; esters such as methyl formate, methyl lactate, ethyl lactate, methyl acetate, ethyl acetate, butyl acetate, methyl pyruvate, methyl acetoacetate, ethyl acetoacetate, ethyl pyruvate, ethyl ethoxyacetate, methyl methoxypropionate, ethyl ethoxypropionate, 2-hydroxy methyl propionate, 2-hydroxy ethyl propionate, 2-hydroxy-2-methyl ethyl propionate, 2-hydroxy-3-methylbutanoic acid methyl, 3-methoxy butyl acetate, and 3-methyl-3-methoxy butyl acetate; aromatic hydrocarbons such as toluene and xylene, and the like. These may be used singly, or two or more kinds may be used in mixture.

The content of the organic solvent (S) is not particularly limited within a range where the objects of the present invention are not impaired. It is preferable that the organic solvent (S) is used in such a range that the solid content concentration of the composition is 30% by mass or more and 70% by mass or less.

### <Other Additives>

The above-mentioned photosensitive resin composition may further contain a surfactant for improving coating, defoaming, leveling properties, and the like. As the surfactant, for example, a fluorinated surfactant and a silicone surfactant are preferably used. Specific examples of the fluorinated surfactant include commercially available fluorochemical surfactants such as BM-1000 and BM-1100 (both are manufactured by B.M-Chemie Co., Ltd.), Megafac F142D, Megafac F172, Megafac F173 and Megafac F183 (all of which are manufactured by Dainippon Ink And Chemicals, Incorporated), Flolade FC-135, Flolade FC-170C, Flolade FC-430 and Flolade FC-431 (all of which are manufactured by Sumitomo 3M Ltd.), Surflon S-112, Surflon S-113, Surflon S-131, Surflon S-141 and Surflon S-145 (all of which are manufactured by Asahi Glass Co., Ltd.), SH-28PA, SH-190, SH-193, SZ-6032 and SF-8428 (all of which are manufactured by Toray Silicone Co., Ltd.) but there is no limitation to those. As the silicone surfactant, a non-modified silicone surfactant, a polyether modified silicone surfactant, a polyester modified silicone surfactant, an alkyl modified silicone surfactant, an aralkyl modified silicone surfactant, a reactive silicone surfactant and the like can be preferably used. As the silicone surfactant, a commercially available silicone surfactant can be used. Specific examples of the commercially available silicone surfactant include Paintad M (manufactured by Dow Corning Toray Co., Ltd.), TOPICA K1000, TOPICA K2000 and TOPICA K5000 (all of which are manufactured by Takachiho Sangyo Co., Ltd.), XL-121 (polyether modified silicone surfactant, manufactured by Clariant), BYK-310 (polyester modified silicone surfactant, manufactured by BYK-Chemie GmbH), and the like.

Furthermore, the above-mentioned composition may contain an antioxidant. The antioxidant is not particularly limited, and conventionally known antioxidants can be used. Examples thereof include a hindered phenol antioxidant, a hindered amine antioxidant, a phosphorus antioxidant, a sulfur antioxidant, and the like.

Furthermore, the above-mentioned composition may contain a polymerization inhibitor in order to appropriately inhibit polymerization during reaction. The polymerization inhibitor is not particularly limited, and conventionally known polymerization inhibitors can be used. Examples thereof include methoquinone, hydroquinone, methyl hydroquinone, p-methoxy phenol, pyrogallol, tert-butyl catechol, phenothiazine, and the like.

Furthermore, the above-mentioned composition may contain an adhesion improving agent in order to improve adhesion to metal wiring or a substrate for electric and electronic devices having metal wiring. The adhesion improving agent is not particularly limited, and conventionally known adhesion improving agents can be used. Examples thereof include benzotriazole and the like.

### <Method of Preparing Composition>

The above-mentioned composition is prepared by mixing and stirring the above-mentioned components by the common method. Devices capable of being used for mixing and stirring the above components include dissolvers, homogenizers, 3-roll mills and the like. After the above components are uniformly mixed, the obtained mixture may be filtered through a mesh, a membrane filter, and the like.

### <<Method for Forming Insulating Part>>

An insulating part for insulating metal wiring in the electric and electronic devices having the metal wiring can be formed using the above-mentioned composition. In other words, a method for forming an insulating part of the present invention includes applying or filling the above-mentioned composition to at least a position in which an insulating part is formed on a substrate for electric and electronic devices having metal wiring; and exposing the applied or filled composition.

In the method for forming an insulating part, firstly, the above-mentioned composition is applied or filled to at least a position in which an insulating part is formed on a substrate for electric and electronic devices having metal wiring. As the application method of the composition to the substrate, methods such as a spin coating method, a slit coating method, a roll coating method, a screen printing method, and an applicator method can be employed. A thickness of a layer of composition formed by application or filling is not particularly limited, but it is preferably 0.5 μm or more, preferably 0.5 μm or more and 300 μm or less, particularly preferably 1 μm or more and 150 μm or less, and most preferably 3 μm or more and 50 μm or less.

Next, the applied or filled composition layer is preferably dried or pre-baked as necessary. The conditions for pre-baking may differ depending on the components in a composition, the blending ratio, the thickness of a coating film and the like. They are usually about 2 minutes or more and 120 minutes or less at 70° C. or more and 200° C. or less, and preferably 80° C. or more and 150° C. or less.

The dried or pre-baked composition layer is irradiated with (exposed to) an active ray or radiation, for example, an ultraviolet radiation or visible light with a wavelength of 300 nm or more and 500 nm or less as necessary. Exposure may be performed to an entire surface of the composition layer, or selective exposure (pattern exposure) in which exposure is performed in a position-selective manner, for example, exposure with an active ray or radiation was performed via a mask having a predetermined pattern. The resin (A) or the radical polymerizable compound (B) as a polymerization component is polymerized by exposure, and an insulating part is formed. Thus, an insulating part is formed on a substrate for electric and electronic devices having metal wiring.

Low pressure mercury lamps, high pressure mercury lamps, super high pressure mercury lamps, metal halide lamps, argon gas lasers, etc. can be used for the light source of the radiation. The radiation may include micro waves, infrared rays, visible lights, ultraviolet rays, X-rays, y-rays, electron beams, proton beams, neutron beams, ion beams, etc. The irradiation dose of the radiation may vary depending on the constituent of the composition, the film thickness of the composition layer, and the like. For example, when an ultra-high-pressure mercury lamp is used, the dose may be 100 mJ/cm² or more and 10,000 mJ/cm² or less. The radiation may include a light ray to activate the radical initiator (C) to generate radical.

In a case of selective exposure, the exposed composition layer is developed by a conventionally known method, and unnecessary portion is removed by dissolution, and thereby an insulating part having a predetermined shape is formed. At this time, as the developing solution, the above-mentioned organic solvent (S) or an alkaline aqueous solution can be used. For example, when the above-described resin (A) has an alkali soluble group such as a carboxy group or a phenolic hydroxyl group, development by an alkaline aqueous solution can be performed.

As the alkaline aqueous solution to be used as a developing solution, for example, an aqueous solution of alkalis such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5,4,0]-7-undecene, and 1,5-diazabicyclo[4,3,0]-5-nonane can be used. Also, an aqueous solution prepared by adding an adequate amount of a water-soluble organic solvent such as methanol or ethanol, or a surfactant to the aqueous solutions of the alkalis can be used as the developing solution.

The developing time may vary depending on the composition of the composition, the film thickness of the composition layer, and the like. Usually, the developing time is 1 minute or more and 30 minutes or less. The developing method may be any one of a liquid-filling method, a dipping method, a paddle method, a spray developing method, and the like.

After development, for example, washing with running water for 30 seconds or more and 90 seconds or less, and drying with an air gun, an oven, and the like, are performed.

In this way, an insulating part patterned in a desired shape is formed on the substrate for electric and electronic devices having metal wiring.

Note here that in the above, an example in which the resin (A) and the radical polymerizable compound (B) as the polymerization component are polymerized by exposure to form an insulating part is shown, but the resin (A) and the radical polymerizable compound (B) as polymerization components may be polymerized by heating to form an insulating part.

Since the formed insulating part has a low dielectric constant and a low dielectric loss tangent, the formed insulating part is suitable for an insulating part of in electric and electronic devices having metal wiring to be used in high frequency. For example, the insulating part can be used for insulating part of electric and electronic devices having metal wiring for frequency of 3 GHz or more and 30 GHz or less for 5G communication band candidate or millimeter-wave frequency of 30 GHz or more and 300 GHz or less. Furthermore, since the formed insulating part is excellent in heat resistance, it is suitable for use in formation of forming an insulating part, then heating thereof, and further forming a member such as wiring.

### EXAMPLES

Hereinafter, the present invention is described in more detail by way of Examples, but the present invention is not limited to these Examples.

### <Preparation of Resin (Raw Material Compound) Having Primary Amino Group>

### [Preparation of P1 Precursor]

In a three-neck flask, propylene glycol monomethyl ether acetate (PGMEA) (242 g) was added, and the obtained product was heated to 80° C. under a nitrogen atmosphere. Styrene (85 g), 4-amino styrene (97 g), and an azo polymerization initiator (product name: V-601, manufactured by FUJIFILM Wako Pure Chemical Corporation) (29 g) were dissolved in PGMEA (242 g), and the obtained product was dropped into the three-neck flask over four hours. After completion of dropping, the obtained product was stirred at 80° C. for two hours, and the obtained polymeric solution was dropped to a methanol-water mixed solution (methanol/water=4/1 (on a mass basis)) (2.5 kg) and allowed to reprecipitate to obtain 72.8 g of copolymer (P1 precursor) of styrene and 4-amino styrene. The copolymerization ratio of the obtained P1 precursor was styrene/4-amino styrene=70/30 (on a molar basis).

### [Preparation of P2 Precursor]

P2 precursor having a copolymerization ratio of styrene/4-amino styrene of 80/20 (on a molar basis) was obtained in the same manner as in [Preparation of P1 precursor] except that the blending ratio of monomer was changed.

### [Preparation of P3 Precursor]

P3 precursor having a copolymerization ratio of styrene/4-amino styrene of 90/10 (on a molar basis) was obtained in the same manner as in [Preparation of P1 precursor] except that the blending ratio of monomer was changed.

### [Preparation of P4 Precursor]

P4 precursor having a copolymerization ratio of styrene/4-amino styrene/normal butyl styrene of 60/30/10 (on a molar basis) was obtained in the same manner as in [Preparation of P1 precursor] except that normal butyl styrene was also used as the monomer.

### [Preparation of P5 Precursor]

P5 precursor having a copolymerization ratio of styrene/4-(aminomethyl)styrene of 70/30 (on a molar basis) was obtained in the same manner as in [Preparation of P1 precursor] except that 4-(aminomethyl)styrene was used instead of amino styrene.

### <Preparation of Resin (A)>

### [Preparation of Resin P1]

### (First Step)

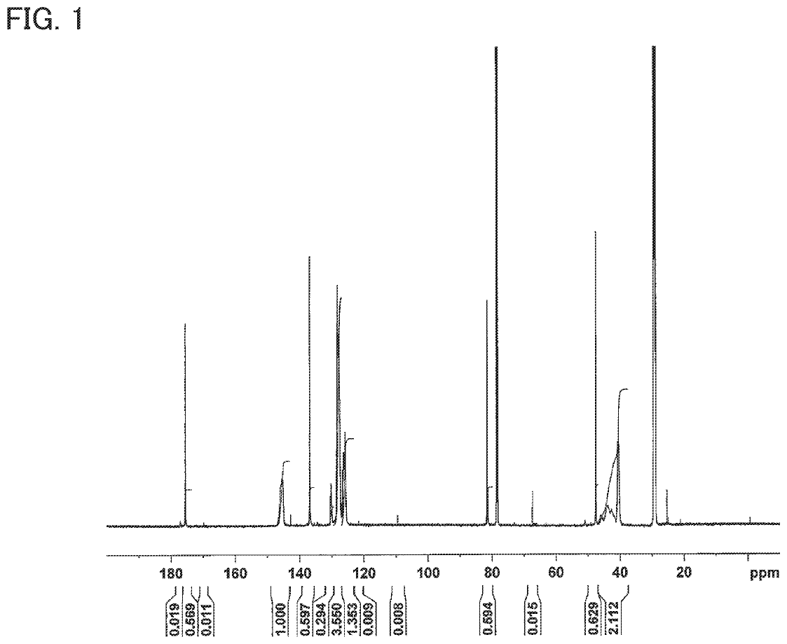

The P1 precursor (72.8 g) and oxonorbornene acid anhydride represented by the following formula (41 g) were dissolved in tetrahydrofuran (THF) (300 g), and the obtained product was stirred under a nitrogen atmosphere for four hours. Subsequently, carbonyl diimidazole (61 g) was added thereto. The obtained product was stirred for six hours, and dropped into heptane (1.5 kg) to reprecipitate to obtain the protected resin 1 (a compound having a group represented by the formula (3)). The composition ratio of the obtained protected resin was calculated from ¹³C NMR. The calculated composition ratio was shown in the following structural formula. The number at the lower right of the parentheses in each constituent unit in the following structural formula represents the content (% by mole) of the constituent unit in each protected resin. Furthermore, from ¹³C NMR, the following structure was verified. The ¹³C NMR measurement result of the protected resin 1 is shown in FIG. 1. Note here that a measurement solvent of ¹³C NMR was acetone-d6.

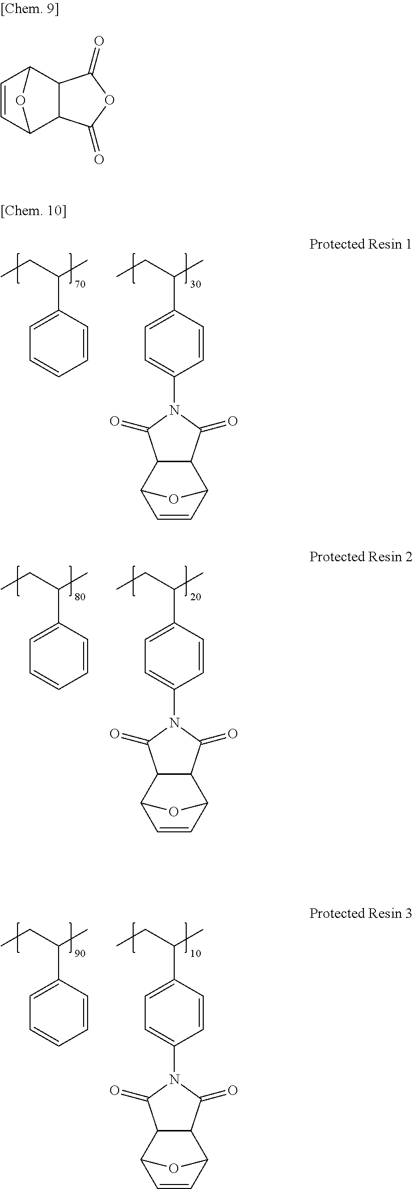

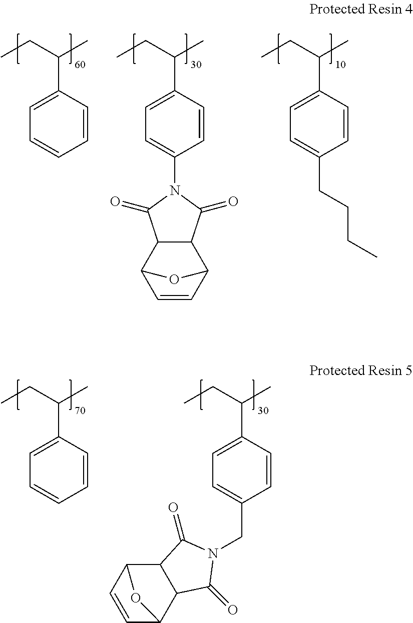

### (Second Step)

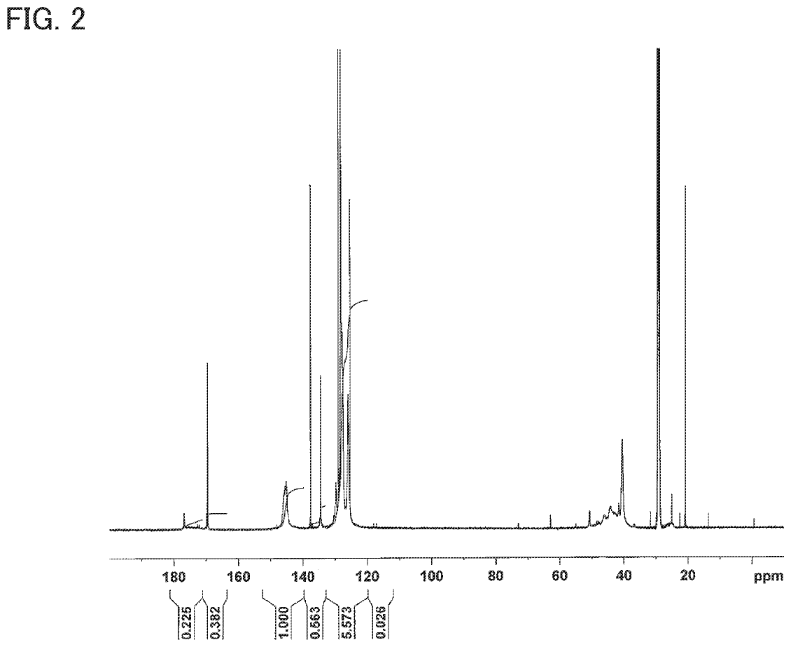

The obtained protected resin 1 was made into 20% by mass toluene solution. The solution was stirred while being refluxed for four hours, and then allowed to reprecipitate with heptane to obtain a solid resin P1 (17.8 g). The composition ratio of the obtained resin was calculated from ¹³C NMR. The calculated composition ratio is shown in the following structural formula. The number at the lower right of the parentheses in each constituent unit in the following structural formula represents the content (% by mole) of the constituent unit in each resin. Furthermore, in ¹³C NMR, a maleimide structure was confirmed from peak of carbonyl and peak of a double bond. The ¹³C NMR measurement result of the resin P1 is shown in FIG. 2. Note here that a measurement solvent of ¹³C NMR was acetone-d6. Furthermore, the mass average molecular weight (Mw) of the obtained resin was obtained by polystyrene conversion of gel permeation chromatography (GPC). The mass average molecular weight (Mw) of the resin P1 was 15000.

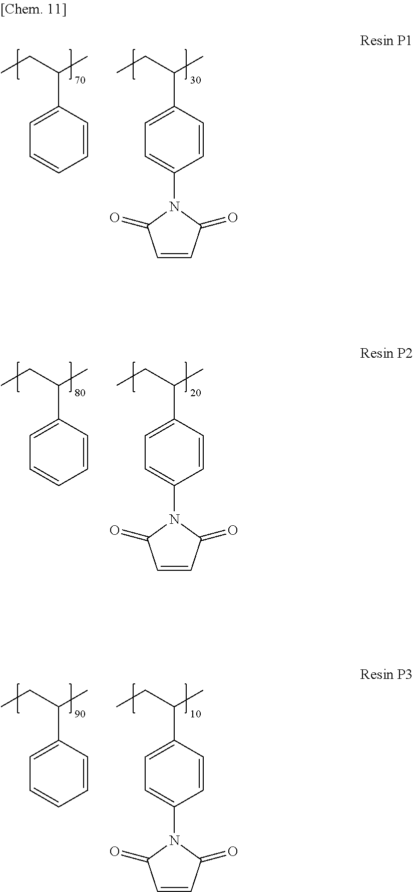

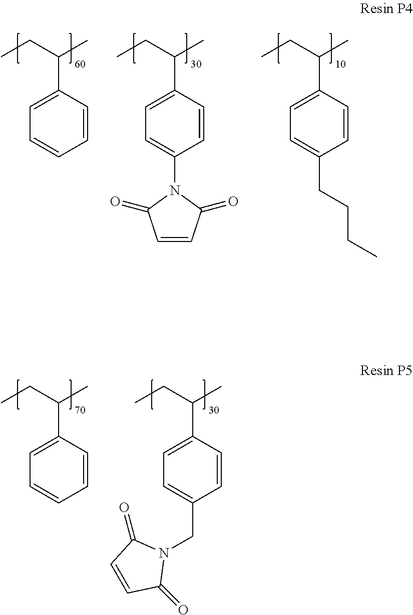

### [Preparation of Resins P2 to P5]

Protected resins 2 to 5 were respectively obtained in the first step and solid resins P2 to P5 were respectively obtained in the second step in the same manner as in [preparation of resin P1] except that precursors P2 to P5 were respectively used instead of the P1 precursor. The mass average molecular weight (Mw) of each of obtained resins P2 to P5 was 15000.

### Preparation of Composition

### Examples 1 to 21 and Comparative Examples 1 to 7

In Examples 1 to 21, the above-mentioned resins P1 to P5 were used as the resin (A). In Examples 1 to 21 and Comparative Examples 1 to 7, as the radical polymerizable compound (B), the following B1 to B5 and B6: SA9000 (manufactured by SABIC INNOVATIVE PLASTICS LIMITED, modified polyphenylene ether obtained by modifying a terminal hydroxyl group of polyphenylene ether with a methacrylic group) were used. Note here that B1 is BMI-689, and B2 is BMI-3000 (both manufactured by Designer molecules).

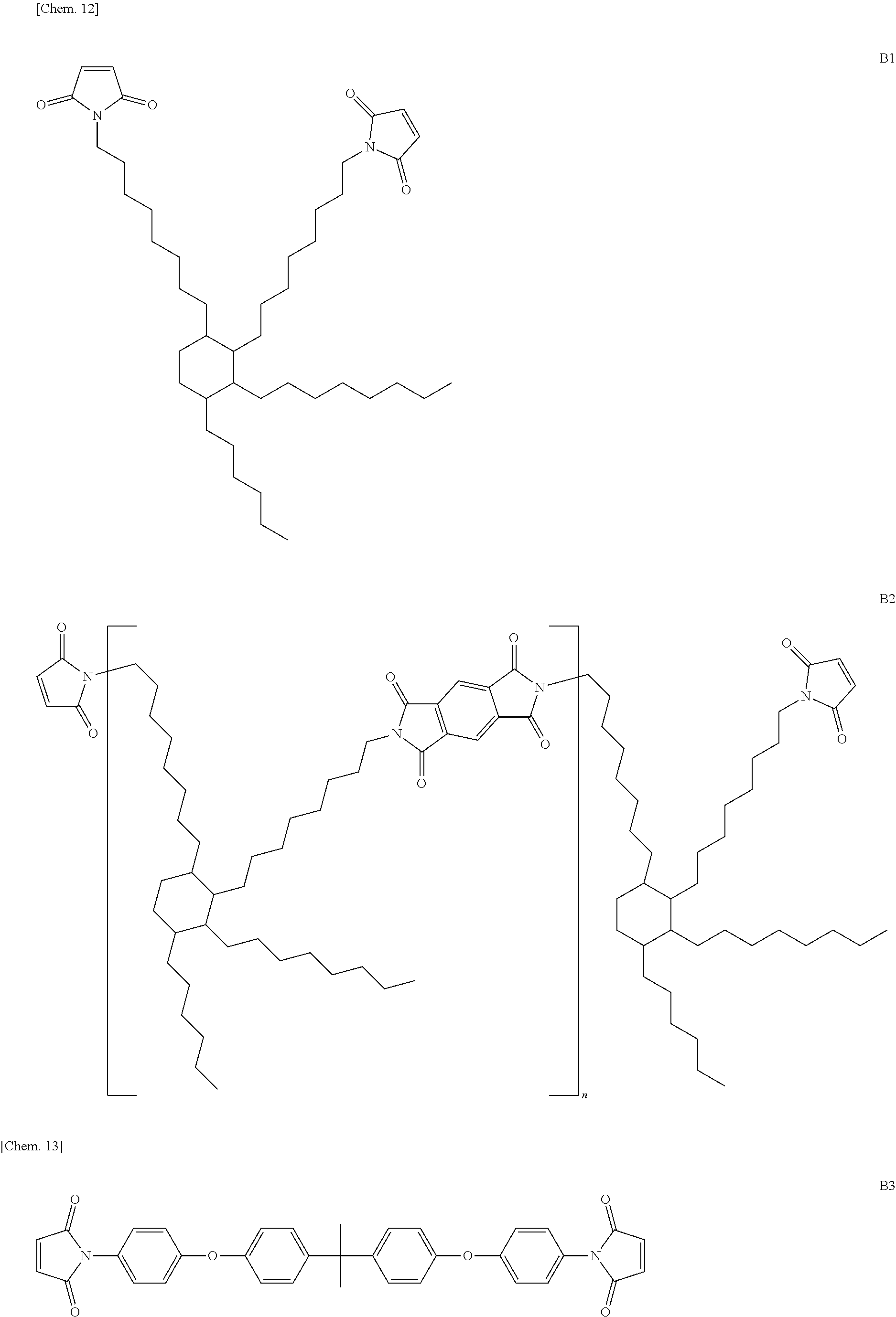

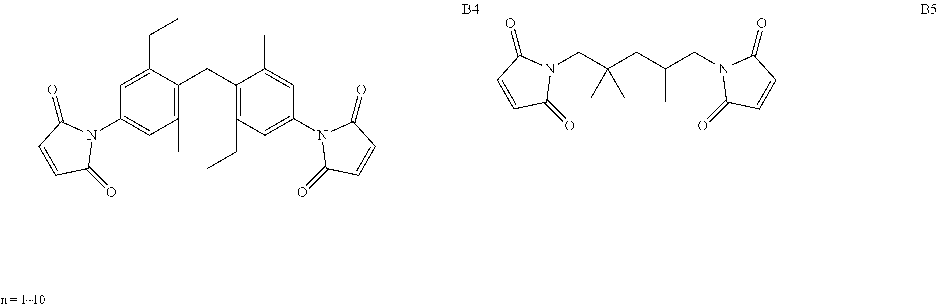 [SMILES: CCc1cc(N2C(=O)C=CC2=O)cc(C)c1Cc1c(C)cc(N2C(=O)C=CC2=O)cc1CC ; CC(CN1C(=O)C=CC1=O)CC(C)(C)CN1C(=O)C=CC1=O]

In Examples 1 to 21, and Comparative Examples 1 to 7, as the radical initiator (C), the following C1 to C4 were used.

C1: Irgacure OXE01 (manufactured by BASF)
C2: Irgacure OXE02 (manufactured by BASF)
C3: Omnirad 819 (manufactured by IGM Resins B.V.)
C4: Perhexyl D (manufactured by NOF CORPORATION)
In Examples 1 to 21, and Comparative Examples 1 to 7, as the additives, the following D1 to D3, and surfactant (BYK310, manufactured by BYK-Chemie GmbH) were used.
D1: Irganox 1010 (manufactured by BASF)
D2: methoquinone
D3: benzotriazole

The resin (A) and/or the radical polymerizable compound (B), the radical initiator (C) and additives of types and amounts described in Tables 1 to 2, and 0.05 part by mass of surfactant (BYK310, BYK-Chemie GmbH) were dissolved in propylene glycol monomethyl ether acetate (PGMEA) such that the solid content concentration became 40% by mass to obtain compositions of Examples and Comparative Examples.

### <Evaluation>

The obtained compositions were evaluated by the following methods in terms of film formability, photolithographic properties, dielectric constant, dielectric loss tangent, and heat resistance. The evaluation results of these are given in Tables 1 to 2.

### [Film Formability and Photolithographic Properties]

The compositions of Examples and Comparative Examples were applied to a Si-substrate having a diameter of 200 mm to form a composition layer (a coating film of the composition). Next, the composition layer was pre-baked (PAB) at 80° C. for 200 seconds. Note here that the pre-baked composition layer had a film thickness of 11 μm. After pre-baking, pattern exposure with a ghi line was performed at an exposure amount of 100 mJ/cm² or more and 4400 mJ/cm² or less using a hole pattern mask capable of forming a circular opening having a diameter of 30 μm and an exposure apparatus Prisma GHI5452 (manufactured by Ultratech, Inc.). Note here that the focus was 0 μm (a composition layer surface). Next, the substrate was put on a hot plate and subjected to post-exposure heating (PEB) at 90° C. for 1.5 minutes. Then, the exposed composition layer was immersed in propylene glycol monomethyl ether acetate (PGMEA) at 60° C. for 60 seconds. Subsequently, the obtained product was blown with nitrogen and heated under nitrogen atmosphere at 180° C. for one hour to obtain a pattern (an insulating part). The surface of the composition layer before pre-baking was observed under scanning electron microscope, and the film formability was evaluated. Specifically, a case where no crack and/or crystal was observed and no tackiness (stickiness) was present on the surface of the composition layer, and the contained components were compatible and transparent is evaluated as o. A case where crack was observed on the surface of the composition layer is evaluated as a; a case where crystal was observed on the surface of the composition layer is evaluated as b; tackiness (stickiness) was present on the surface of the composition layer is evaluated as c; the contained components were not compatible and not transparent is evaluated as d. Furthermore, the surface and cross-section of the obtained pattern (insulating part) were observed under scanning electron microscope to evaluate photolithographic properties. Specifically, in the above-described range of exposure amount, a case where conditions for forming an opening having a diameter of 30 μm were present is evaluated as o, and a case where conditions for forming an opening having a diameter of 30 μm were not present is evaluated as x. Note here that in Comparative Example 1, since pattern (insulating part) was not able to be formed due to tackiness, the dielectric constant, the dielectric loss tangent, and the heat resistance were not evaluated. Furthermore, Comparative Examples 3 and 4, since the composition layer before pre-baking had crack and crystal, the photolithographic properties, the dielectric constant, dielectric loss tangent, and the heat resistance were not evaluated.

### [Dielectric Constant and Dielectric Loss Tangent]

The compositions of Examples and Comparative Examples were applied to a Si-substrate having a diameter of 200 mm to form a composition layer (a coating film of the composition). Next, the composition layer was pre-baked (PAB) at 80° C. for 200 seconds. Note here that the pre-baked composition layer had a film thickness of 11 μm. After pre-baking, an entire surface was exposed with a ghi line at an exposure amount of 4400 mJ/cm² using an exposure apparatus Prisma GHI5452 (manufactured by Ultratech, Inc.). Note here that the focus was 0 μm (a composition layer surface). Subsequently, the composition layer surface was blown with nitrogen and heated at 180° C. for one hour to obtain a sample. The dielectric constant (s) and the dielectric loss tangent (tan δ) of the obtained sample were measured by a method described in IEICE technical report of IEICE Technical Committee, vol. 118, no. 506, MW 2018-158, pp. 13-18, March 2019, “A study on millimeter wave complex permittivity evaluations by the circular empty cavity method for photosensitive insulator” (Kohei Takahagi (Utsunomiya University), Kazuaki Ebisawa (TOKYO OHKA KOGYO CO., LTD.), Yoshinori Kogami (Utsunomiya University), and Takashi Shimizu (Utsunomiya University)). Measurement was performed using Network Analyzer HP8510C (Keysight Technologies, Inc.) by the empty cavity method in the conditions in which room temperature is 25° C., humidity is 50%, frequency is 36 GHz, and sample thickness is 10 μm. A case where the dielectric constant value was less than 3.00 is evaluated as o, and a case where it is 3.00 or more is evaluated as x. A case where the dielectric loss tangent value was less than 0.01 is evaluated as 0, and a case where it is 0.01 or more id evaluated as x.

[Heat resistance]

As to the samples obtained by the same technique as that in the item [Dielectric constant and dielectric loss tangent], a peak top temperature (° C.) of tan δmeasured using a dynamic viscoelastic device Rheogel-E4000 (manufactured by UMB Co., Ltd.) was made to be a glass transition temperature (Tg) (DMA method). The measurement conditions were as follows. Measurement mode: tension mode, Frequency: 10 Hz, Temperature increasing rate: 5° C./min, Measurement temperature range: 40 to 300° C., Sample shape: 50 mm in length, 5 mm in width, and 10 μmm in thickness. Heat resistance was evaluated as follows: a case where Tg was 150° C. or more is evaluated as o; a case where Tg is less than 150° C. is evaluated as x.

TABLE 1

| | | Radical | | | | | | | |
|---|---|---|---|---|---|---|---|---|---|
| | | polymerizable | Radical | | | | | | |
| | Resin | compound | initiator | | Evaluation | | | | |
| | (A) | (B) | (C) | Additives | | Photolitho- | | Dielectric | |
| | Types/part | Types/part | Types/part | Types/part | Film | graphic | Dielectric | loss | Heat |
| | by mass | by mass | by mass | by mass | formability | properties | constant | tangent | resistance |
| Example 1 | P1/80 | B1/20 | C2/3 | D2/0.05 | ○ | ○ | ○ | ○ | ○ |
| Example 2 | P1/40 | B1/60 | C4/1 | | ○ | ○ | ○ | ○ | ○ |
| Example 3 | P1/80 | B5/20 | | | ○ | ○ | ○ | ○ | ○ |
| Example 4 | P1/60 | B5/40 | | | ○ | ○ | ○ | ○ | ○ |
| Example 5 | P2/80 | B1/20 | | | ○ | ○ | ○ | ○ | ○ |
| Example 6 | P2/60 | B1/40 | | | ○ | ○ | ○ | ○ | ○ |
| Example 7 | P2/80 | B5/20 | | | ○ | ○ | ○ | ○ | ○ |
| Example 8 | P3/80 | B5/20 | | | ○ | ○ | ○ | ○ | ○ |
| Example 9 | P3/80 | B1/20 | | | ○ | ○ | ○ | ○ | ○ |
| Example 10 | P4/80 | B5/20 | | | ○ | ○ | ○ | ○ | ○ |
| Example 11 | P4/80 | B1/20 | | | ○ | ○ | ○ | ○ | ○ |
| Example 12 | P5/80 | B5/20 | | | ○ | ○ | ○ | ○ | ○ |
| Example 13 | P5/80 | B1/20 | | | ○ | ○ | ○ | ○ | ○ |
| Example 14 | P2/50 | B1/40 | | | ○ | ○ | ○ | ○ | ○ |
| | | B6/10 | | | | | | | |
| Example 15 | P2/80 | B1/20 | | D1/1 | ○ | ○ | ○ | ○ | ○ |
| Example 16 | | | | D2/0.05 | ○ | ○ | ○ | ○ | ○ |
| Example 17 | P3/50 | B1/40 | | D3/0.5 | ○ | ○ | ○ | ○ | ○ |
| | | B4/10 | | | | | | | |
| Example 18 | | B1/40 | | | ○ | ○ | ○ | ○ | ○ |
| | | B3/10 | | | | | | | |
| Example 19 | P2/80 | B5/20 | C1/3 | | ○ | ○ | ○ | ○ | ○ |
| | | | C4/1 | | | | | | |
| Example 20 | | | C3/3 | | ○ | ○ | ○ | ○ | ○ |
| | | | C4/1 | | | | | | |
| Example 21 | P4/100 | — | C2/3 | — | ○ | ○ | ○ | ○ | ○ |
| | | | C4/1 | | | | | | |

TABLE 2

| | | Radical | | | | | | | |
|---|---|---|---|---|---|---|---|---|---|
| | | polymerizable | Radical | | | | | | |
| | Resin | compound | initiator | | Evaluation | | | | |
| | (A) | (B) | (C) | Additives | | Photolitho- | | Dielectric | |
| | Types/part | Types/part | Types/part | Types/part | Film | graphic | Dielectric | loss | Heat |
| | by mass | by mass | by mass | by mass | formability | properties | constant | tangent | resistance |
| Comparative | — | B1/100 | C2/3 | D2/0.05 | c | x | — | — | — |
| Example 1 | | | C4/1 | | | | | | |
| Comparative | — | B2/100 | | | ○ | ○ | ○ | ○ | x |
| Example 2 | | | | | | | | | |
| Comparative | — | B3/100 | | | a | — | — | — | — |
| Example 3 | | | | | | | | | |
| Comparative | — | B4/100 | | | b | — | — | — | — |
| Example 4 | | | | | | | | | |
| Comparative | — | B2/50 | | | d | x | ○ | ○ | x |
| Example 5 | | B3/50 | | | | | | | |
| Comparative | — | B2/50 | | | d | x | ○ | ○ | x |
| Example 6 | | B4/50 | | | | | | | |
| Comparative | — | B2/50 | | | d | x | ○ | ○ | x |
| Example 7 | | B5/50 | | | | | | | |

According to Examples 1 to 21, it is shown that a composition including the resin (A) having a group represented by the formula (a1) at a specific position can be formed into an insulating part having a low dielectric constant, a low dielectric loss tangent, and excellent heat resistance, and is excellent in film formability. Furthermore, in the composition of Examples 1 to 21, the resin (A) was dissolved in PGMEA. Also, Examples 1 to 21 show excellent photolithographic properties.

On the other hand, according to Comparative Examples 1 to 7, when the resin (A) is not contained, a composition capable of being formed into an insulating part having a low dielectric constant, a low dielectric loss tangent, and excellent heat resistance, and having excellent film formability is not be achieved.

What is claimed is:

1. A composition used to form an insulating part for insulating metal wiring in electric and electronic devices having the metal wiring,
wherein the composition comprises a resin (A) having a group represented by the following formula (a1),
wherein the group represented by the formula (a1) is bonded to a carbon atom in an aliphatic hydrocarbon group or an aromatic group in a main chain and/or a side chain of the resin (A), the carbon atom being located in a position other than a terminal of the main chain of the resin (A),
the group represented by the formula (a1) is a group represented by the following formula: 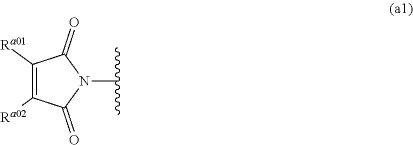
wherein R^{a01} and R^{a02} are each independently a hydrogen atom, an alkyl group having 1 or more and 6 or less carbon atoms, a cycloalkyl group having 3 or more and 8 or less carbon atoms, or an aryl group having 6 or more and 12 or less carbon atoms.

2. The composition according to claim 1, wherein the main chain is derived from a (meth)acrylic resin or a polystyrene resin.

3. The composition according to claim 1, further comprising a radical initiator (C).

4. The composition according to claim 3, wherein the radical initiator (C) is a photo-radical initiator.

5. The composition according to claim 3, further comprising a radical polymerizable compound (B).

6. The composition according to claim 5, wherein the radical polymerizable compound (B) comprises a radical polymerizable compound having the group represented by the formula (a1).

7. The composition according to claim 1, wherein R^{a01} and R^{a02} are each a hydrogen atom.

8. A method for forming an insulating part, the method comprising:
applying or filling the composition according to claim 1 to at least a position provided with an insulating part on a substrate for electric and electronic devices having metal wiring; and
exposing the applied or filled composition.

9. The method according to claim 8, wherein the exposure is performed in a position-selective manner, and
the method comprises developing the composition exposed in a position-selective manner with a developing solution.
